(19) United States
(12) Patent Application Publication
(10) Pub. No.: US 2025/0208173 A1
(43) Pub. Date: Jun. 26, 2025

(54) Whole House Electricity Sensor

(71) Applicant: Robert Dickerman, Northfield, MA (US)

(72) Inventor: Robert Dickerman, Northfield, MA (US)

(21) Appl. No.: 19/078,894

(22) Filed: Mar. 13, 2025

(51) Int. Cl. G01R 15/20; G01R 19/00; G01R 33/00

(52) U.S. Cl. CPC G01R 15/207; G01R 19/0092; G01R 33/0041; G01R 33/0094

(57) ABSTRACT

Devices and methods for making independent measurements of electricity flowing through a meter equipment that is being used for fiscal metering of electricity are disclosed. The devices comprise at least one magnetic field sensor that is substantially coupled to a magnetic field radiated from within the meter equipment. The magnetic field sensor is mounted externally to and adjacent to the meter equipment.

### FIELD AND BACKGROUND OF THE INVENTION

This disclosure relates to electricity monitoring by customers of electric utilities, for the purpose of energy conservation and reducing customers' electricity bills. A whole-house electricity monitor allows a customer to easily monitor their home's total electricity usage in real-time by displaying their home's power and energy on an indoor or portable display. This produces a heightened awareness of electricity usage. The use of a whole-house electricity monitor typically engenders behavior modification in residents that reduces household energy consumption by 5% to 10%.

Furthermore, if a monitor has a portable display, and it can update readings about once per second, it can also be used to estimate the consumption of individual appliances. A user can gauge an appliance's power draw by noting the changes in whole-house power as an appliance turns on and off.

Electricity monitors are commercially available, but they are all saddled with deficiencies that prevent their widespread adoption.

What are these deficiencies? They are not unavailability, or a lack of accuracy; a variety of monitors have been available for decades, and only rough indications of consumption are needed to guide consumers in conservation. Rather, the dominant barriers to widespread adoption are likely the inconvenience, hazard, and high cost of installation of conventional monitors. In addition, the readings of some devices update slowly, and some are unable to make measurements independently of the utility meter's readings.

In this application, “monitoring electricity” means, amongst other things, “estimating power and energy use”. Electrical power is voltage times current (when power factor=1.00), so to estimate power, one needs to know both voltage and current. However, while household voltage is typically almost constant (nominally 240.0 VAC or 120.0 VAC, with variations of +/−10.0%), current can vary over 4 decades or more. Consequently, all whole-house monitors measure current, but some don't measure voltage-they just assume nominal values of voltage.

To measure current, most conventional whole-house monitors employ at least two split-core current transformers that must be mounted on individual conductors inside a home's circuit breaker panel, after first removing the front cover of the circuit breaker panel. Most of these monitors must also be hard-wired to 120 volts alternating current (VAC) inside the circuit breaker panel to power the monitor itself. These aspects expose the installer to live, uninsulated conductors and shock hazards. Consequently, safety and liability concerns dictate that conventional monitors should be installed by licensed electricians; in fact, this is stated explicitly in most conventional monitors' user manuals. However, hiring an electrician is costly and inconvenient.

Other conventional whole-house monitors are “meter-mounted”, meaning that they are mounted on the exterior of the utility fiscal electricity meter. The term fiscal electricity meter, as used here, means a meter used by an electric utility to determine consumption so that a utility customer may be properly billed. These are the ubiquitous glass-domed or plastic-domed meters that are typically mounted on the exterior walls of dwellings, usually at “eye height”, so that a utility employee can read, examine, or configure the meter with ease. Conventional meter-mounted monitors do avoid the shock hazards and safety and liability concerns of the conventional current transformer monitors. However, conventional meter-mounted monitors are parasitic devices-they do not make their own independent measurements of power and energy. Instead, they intercept and display measurements that have been made by the utility electric meter. Various conventional designs either optically sense the position of a spinning disk in a legacy utility meter, or they optically sense readout infrared light pulses emitted by a utility meter, or they intercept smart meter Automatic Meter Reading (AMR) or Advanced Metering Infrastructure (AMI) radio reports from a utility meter. A disadvantage of this parasitic aspect is that, in some instances, the impetus for a customer to install an electricity monitor is a sudden sharp increase in his or her electric bill-often, just after a new “smart meter” has been installed by the utility. In these instances, the customer wants to obtain independent measurements of power and energy, to verify that they are not being overcharged by the utility due to a faulty meter. Measurements that have been regurgitated from the suspect utility meter will not help such a customer. Furthermore, the update rate for the power readings from many conventional meter-mounted monitors is too slow to be useful for identifying individual appliance consumption (by watching readings change as an appliance turns on or off). Additionally, utility meter infrared light outputs are not always accessible; and even when they are accessible, it may be difficult or impossible to align the monitor's optical sensors to capture those outputs. Furthermore, the monitor's optical sensors are sometimes incompatible with the customer's utility meter. Finally, many utilities simply do not allow customer access to AMR and AMI radio links.

To mitigate these deficiencies, the whole house electricity monitor must be made safer to install, easier to install, and cheaper to install, be universally compatible with residential electrical installations, and must make its own measurements of power and energy, independently of the utility's electric meter.

### BRIEF DESCRIPTION OF DRAWINGS

Various apparatuses in accordance with the present disclosure will be described with reference to the drawings, in which:

FIG. 1A shows a prior art utility fiscal meter mated to a meter socket;

FIG. 1B shows a side view of a prior art utility fiscal meter;

FIG. 1C shows a prior art meter socket;

FIG. 1D shows a sectional side view of a prior art utility fiscal meter mated with a ring style meter socket;

FIG. 2A shows a schematic view of a magnetic sensor mounted on a meter socket in accordance with an embodiment;

FIG. 2B shows a magnetic sensor mounted on a meter socket in accordance with an embodiment;

FIG. 3A shows a schematic view of a plurality of magnetic sensors mounted on a meter socket in accordance with an embodiment;

FIG. 3B shows a schematic view of a plurality of magnetic sensors and a plurality of electrodes mounted on a meter socket in accordance with an embodiment;

FIG. 4 shows a block diagram of an analyzer with a converter in accordance with an embodiment;

FIG. 5A shows a block diagram of a line voltage plug sensor with a wired output in accordance with an embodiment;

FIG. 5B shows a block diagram of a line voltage plug sensor with a wireless output in accordance with an embodiment;

FIG. 5C shows a schematic of an electric field sensor in accordance with an embodiment;

FIG. 5D shows a schematic of an electric field sensor in accordance with an embodiment;

FIG. 5E shows a schematic of a comparator in accordance with an embodiment;

FIG. 5F shows a block diagram of a phase-locked loop in accordance with an embodiment;

FIG. 5G shows a block diagram of a free-running oscillator in accordance with an embodiment;

FIG. 6A shows a detailed block diagram of a phase-locked loop in accordance with an embodiment;

FIG. 6B shows a detailed block diagram of an all-digital phase-locked loop in accordance with an embodiment;

FIG. 7A shows a block diagram of a single-phase analyzer with a converter in accordance with an embodiment;

FIG. 7B shows a block diagram of a dual-phase analyzer in accordance with an embodiment;

FIG. 8A shows a top view of a sensor assembly with a single magnetic sensor in accordance with an embodiment;

FIG. 8B shows a side view of a sensor assembly with a single magnetic sensor in accordance with an embodiment;

FIG. 8C shows a top view of an annular ring sensor assembly with a plurality of magnetic sensors in accordance with an embodiment;

FIG. 8D shows a side view of an annular ring sensor assembly with a plurality of magnetic sensors in accordance with an embodiment;

FIG. 8E shows a top view of a partial annular ring sensor assembly with a plurality of magnetic sensors in accordance with an embodiment.

FIG. 8F shows a side view of a partial annular ring sensor assembly with a plurality of magnetic sensors in accordance with an embodiment.

### REFERENCE NUMERALS

110 meter socket
112 meter
113 rim
114 ringless meter socket cover
116 stab
118 stab
120 jaw
122 jaw
124 jaw
126 jaw
128 perimeter
129 latch
130 meter ring
132 stab
134 stab
136 ring style meter socket cover
210 magnetic sensor
310 magnetic sensor
312 magnetic sensor
314 magnetic sensor
316 magnetic sensor
318 magnetic sensor
320 center axis of meter
322 reference line
324 electrode
326 electrode
410 analyzer
412 magnetic sensor signal
414 central value of magnetic sensor signal
416 converter
418 central value of current
510 line voltage plug
512 line voltage plug sensor with wired output
514 cable
516 reference signal
518 power signal
520 voltage size signal
522 line voltage sensor
524 radio interface
526 radio
528 antenna
530 radio signal
532 antenna
534 radio
536 first AC line
538 parasitic coupling capacitor
540 capacitor
542 resistor
544 analog E field signal
546 feedback capacitor
548 feedback resistor
550 opamp
551 second AC line
552 parasitic coupling capacitor
554 feedback capacitor
556 feedback resistor
558 opamp
560 difference amplifier
562 comparator input
564 comparator
566 comparator output
568 PLL reference input
570 PLL
572 free-running oscillator
610 phase detector
612 loop filter
614 oscillator
616 all-digital PLL
618 clock input
710 single-phase analyzer
712 phase shifter
714 multiplier
716 product signal
718 lowpass filter
720 dual-phase analyzer
722 90° phase shifter
724 multiplier
726 lowpass filter
728 in-phase output (I)
730 quadrature output (Q)
810 base
812 base
814 base
816 alignment element
818 alignment element
820 alignment element
822 alignment element
824 label

### DETAILED DESCRIPTION

Disclosed herein is a novel whole-house electricity sensor that may be used to provide real-time information about a home's electricity usage to a utility customer.

The apparatuses of the present disclosure overcome the disadvantages of conventional electricity monitors by allowing a simple and convenient installation of a sensor on the exterior of a user's utility meter equipment, and by allowing relatively rapid measurements of whole-house electrical power that are independent of the utility meter's measurements.

Mounting the sensor at this location-on the exterior of a user's utility meter equipment-yields a breakthrough in ease of installation, which is essential for wide adoption. All residential electric utility meters and meter socket openings look alike and are familiar to customers, and utilities mandate that meters be exposed and mounted at face height, for easy access. Furthermore, there is no electrical hazard associated with the exterior of an installed utility meter and socket. Therefore, anyone can safely and easily install the novel monitor without the services of an electrician. Additionally, unlike prior-art monitors that are utility-meter-mounted, the disclosed electricity sensor makes independent measurements of power. As mentioned previously, this is important to some users who have noticed abrupt—and unpleasant—increases in electricity bills after having a new utility “smart meter” installed.

Embodiments exploit the considerable standardization of residential utility meters and sockets. This standardization results in a uniformity of conductor geometry that is unmatched in any other part of the residential service entrance equipment. This uniformity allows the relative orientation and spacing of a sensor with respect to a target current-carrying conductor to be predetermined and approximately fixed, thereby mitigating variations in an overall gain of the sensor.

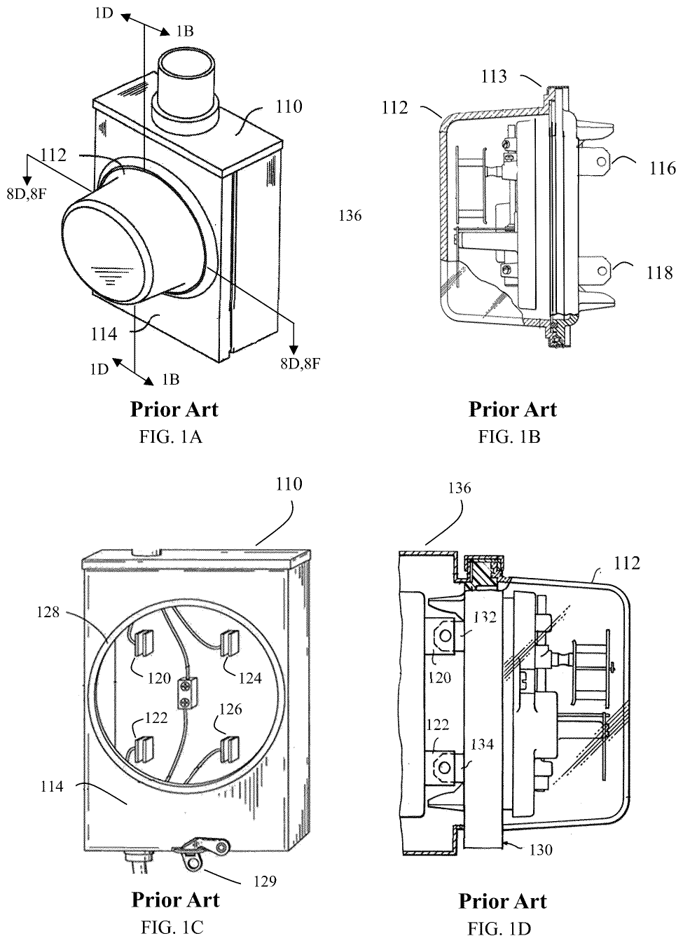

FIGS. 1A-1D are prior art illustrations of examples of utility meter equipment, shown here for context.

FIG. 1A shows a meter 112 mounted in a meter socket 110. A meter equipment comprises socket 110, cover 114, and meter 112, for example, and in some installations includes a meter ring, discussed below. Meter 112 is mated to socket 110 when in use.

Most residential fiscal meters and sockets are ANSI Form 2S. This means that a meter has four male connector blades, dubbed “stabs”, and a mating socket has four female connecting terminals, dubbed “jaws”. FIG. 1B shows a side view of meter 112, wherein two stabs 116, 118 (of its four) are visible. FIG. 1C shows a view of socket 110 with no installed meter. Here, jaws 120, 122, 124, 126 are visible. When meter 112 is plugged into a compatible socket, its four male stabs mate with the corresponding four female jaws of the socket. In the sectional side view drawing of FIG. 1D, for example, a stab 132 mates with jaw 120, and a stab 134 mates with jaw 122.

In FIG. 1C, a first line current I_{L1} flows from jaw 120 (through meter 112) to jaw 122, and a second line current I_{L2} flows from jaw 124 (through meter 112) to jaw 126.

There are two styles of ANSI Form 2S meter mounting: ringless and ring style.

Referring to FIGS. 1C and 1B, for ringless mounting, cover 114 is first removed (not shown), and meter 112 is plugged into socket 110. Then, cover 114 is slid over meter 112 onto socket 110, and secured with a latch 129. A perimeter 128 of cover 114 engages a rim 113 of meter 112 to prevent its removal. Finally, latch 129 is locked with a locking tag (not shown) through a hole in latch 129.

Alternatively, ring style mounting is shown in the partial sectional view of FIG. 1D. Here, a ring style meter socket cover 136 is first installed over the meter socket. Then, meter 112 is plugged into the socket through an opening in installed cover 136. Next, a split meter ring 130 is spread and installed over rim 113 of the meter and a lip on a perimeter of the opening in cover 136 (meter ring 130 is shown with a partially sectional view at the top of the drawing). Meter ring 130 engages the rim and the lip, and is tightened around them, thus securing meter 112 to the meter socket. After it is tightened, meter ring 130 is locked closed with a locking tag (not shown).

For meter equipment that substantially conforms to the specifications of ANSI Form 2S, the dimensions of the stabs and jaws are fixed and known. The locations and orientations of the stabs and jaws with respect to perimeter 128 of an opening in a ringless meter socket cover 114, or with respect to meter ring 130 for a ring style socket, are also fixed and known. An orientation of a layout of the four jaws with respect to the meter cover 114 or 136 is fixed and known.

The novel electricity sensor is deployed externally to the meter equipment being used for residential fiscal metering of electricity. An embodiment comprises at least one magnetic field sensor located externally to and substantially adjacent to a perimeter of a circular opening in a cover of the meter equipment, and a base for mounting the magnetic field sensor on the meter equipment at a predetermined location and orientation with respect to the meter equipment.

The magnetic field sensor is substantially coupled to a magnetic field radiated from within the meter equipment by an electrical current in at least one conductor, the conductor being located inside the meter equipment. The conductor carries one of the two line currents I_{L1}, I_{L2} that are essentially measured by the meter equipment to determine watt-hours. The magnetic field sensor may, in some embodiments, be substantially coupled to both line currents. An output from the magnetic field sensor is a magnetic sensor signal that may be used to estimate a value of the electrical current.

The magnetic field sensor may be positioned adjacent to a conductor or adjacent to several conductors located within the meter equipment that are targeted for measurement. In various embodiments, the targeted conductor may comprise one of the various four jaws 120, 122, 124, 126, or a jaw of the meter socket and a corresponding mated stab of the meter, or pairs of jaws and their corresponding mating stabs, or all four jaws and their mating stabs. In such embodiments, the device targets, and is substantially responsive to, the magnetic field caused by the current flowing in the jaw-stab pair or pairs.

The magnetic field sensor is attached to, or engaged by, the base, and the base mounts on the meter equipment. The base is located externally to and adjacent to the meter equipment and is interposed between the magnetic field sensor and an external surface of the meter equipment. Thus, the base engages both the magnetic field sensor and an external surface of the meter equipment, and it physically adapts the magnetic field sensor or sensor assembly to fit to the surface of the meter equipment. The base may include alignment elements and markings, to aid the user in placing and registering the sensor with the meter equipment during installation, as will be discussed further below. The base allows the magnetic sensor, after being installed, to be left unattended for days, weeks, months or years at a predetermined location and orientation externally to and adjacent to the meter equipment, without requiring a user to hold the magnetic sensor in place.

The base may comprise a single preformed part, such as a molded or machined housing or enclosure, or part of such a housing or enclosure, that holds the magnetic field sensor and any conductors, wires, cables, or other electrical interconnections and electronics. The base may comprise a part manufactured by any conventional method. The material of the base may be metal, plastic, fiberglass, wood, or any other synthetic or natural material. The base may be employed and formed as a substrate for mounting the sensor and any wires or other electrical interconnections and electronics. For example, the base may comprise a printed-circuit board (PCB) or flexible PCB, or other electrically insulating flexible or rigid substrate. Furthermore, the base may comprise a combination of several connected parts, such as a rigid or flexible PCB mounted in a housing and held in place on the meter equipment with fasteners, such as clips, for example. At a minimum, the base may comprise a suitably formed surface of the magnetic sensor itself, or even just a droplet of adhesive or a patch of adhesive tape that attaches the magnetic sensor to the meter equipment at a predetermined location and orientation.

The base mounts on an exterior surface of the meter equipment. For example, the base may mount on or adjacent to perimeter 128 of the cover opening. Alternatively, if the meter socket is a ring style socket, the base may mount on or adjacent to meter ring 130. The base may be fastened to cover 114 or 136, or to meter ring 130, or to any other part of the meter equipment by using permanent magnets, or permanent magnet strip, or with adhesives or adhesive strips or tapes, or with reusable fasteners such as hook-and-loop or similar fasteners, or with clips, or with wires, or with cable ties, or by using any other conventional mechanical fasteners or conventional fastening method. The base may even be fastened to the meter equipment by compliant clips that contact the dome of meter 112.

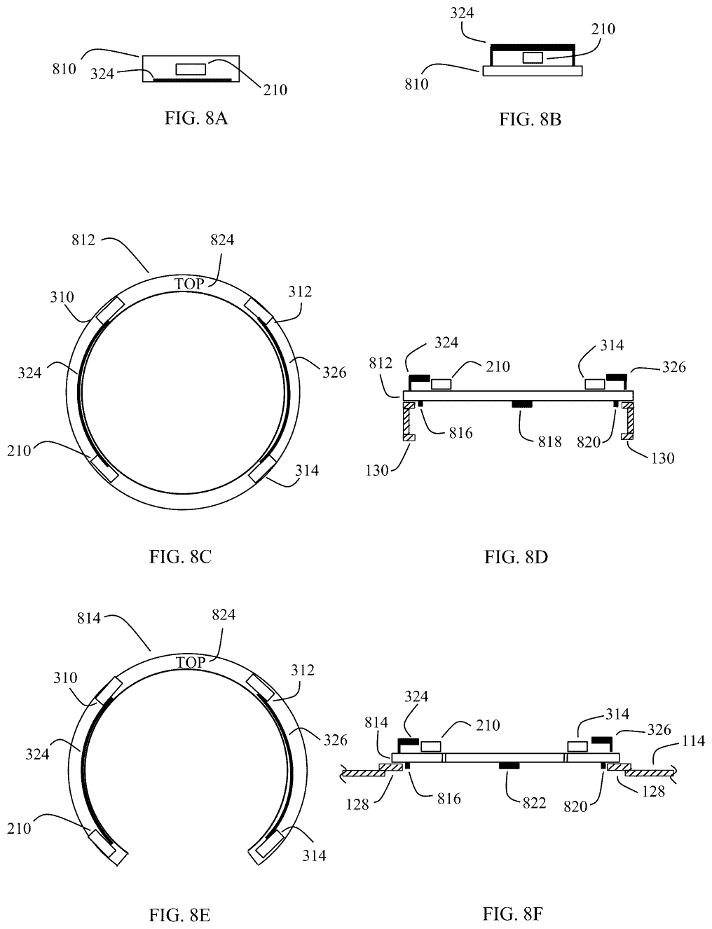

Examples of embodiments of the base, alignment element, and label are shown in FIGS. 8A-8F, and are discussed later.

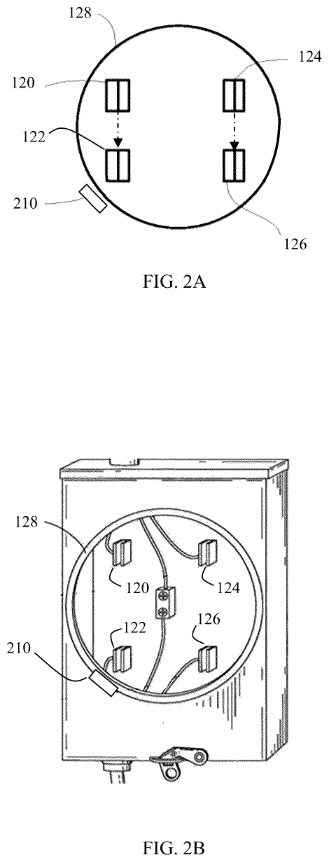

FIGS. 2A and 2B show an example of placement of a magnetic sensor 210 in accordance with an embodiment. Sensor 210 is a magnetic field sensor that is responsive to magnetic fields. Sensor 210 is located adjacent to perimeter 128 of the meter cover opening. Sensor 210 is also substantially adjacent to jaw 122. Because the spacings between the four jaw-stab pairs are relatively large, sensor 210 is substantially responsive to the magnetic field produced by a current flowing in jaw 122 and its mating stab. Because the positions of the stabs and jaws are fixed and known, and the direction of power flow is known, the gain of sensor 210 may be predicted from theory or measured. An output from sensor 210 is the magnetic sensor signal that may be used to estimate a value of the electrical current. A measure of the magnetic sensor signal may, in some embodiments, be converted to an estimate of current as simply as by multiplying by a suitable gain constant (although more sophisticated processing may be employed).

Thus, the novel sensor does not rely upon the principle of Ampere's law (as do most conventional current sensors), which requires that a sensor essentially evaluate a line integral of magnetic field strength in a closed loop path around a current-carrying conductor. On the exterior of the utility meter equipment, individual conductors are not accessible, so none can be encircled individually. Rather, as described above, the novel sensor exploits the considerable standardization of conductor geometry in residential utility meter sockets by making one or more localized magnetic field measurements at predetermined distances and orientations with respect to the conductor, thereby yielding a substantially predictable gain for the sensor. Here, the Biot-Savart law may be used to predict the magnetic field seen by each magnetic field sensor.

Magnetic sensor 210 may comprise a conductor loop, a coil of conductive material, an inductor, a Rogowski coil, a sensor that produces a voltage approximately in accordance with Lenz's Law, a Hall effect sensor, a magnetoresistive sensor, a flux-balancing sensor, or a fluxgate sensor, for example.

Magnetic sensor 210 may be located adjacent to meter socket 110, meter 112, the conductor, such as a jaw of the meter socket and a mated stab of the meter, for example jaw 120 and stab 132, rim 113, perimeter 128, or meter ring 130, or a combination of these.

The position and orientation of the magnetic sensors may be at predetermined displacements from and at predetermined rotations relative to a position and an orientation, respectively, of perimeter 128 of the circular opening, or the circular opening itself, or cover 114, or a rim of meter 112, or socket 110, or the targeted conductor. For example, jaws 120, 122, 124, 126 and their mating stabs may be targeted conductors.

As mentioned above, a position and an orientation of the conductor relative to the circular opening and the meter socket may be substantially prescribed by specifications pertaining to an ANSI standard designation of Form 2S. This allows embodiments to mitigate variation in sensor gain that might otherwise arise. Alternatively, these aspects may be substantially prescribed and fixed by other engineering standards in a similar way.

A responsive axis of the magnetic sensor 210 may be disposed so that the responsive axis is approximately aligned with a magnetic field line substantially radiated by the current in the conductor.

For example, in FIGS. 2A and 2B, sensor 210 is assumed to have a responsive axis that is parallel to the long side of the rectangle shape that represents it in the figures. Such a sensor might comprise a helical coil of wire with its axis parallel to the long side of sensor 210, for example. Here the conductor being targeted is jaw 122 and its mating stab, and the axis of the conductor is a line that is approximately perpendicular to the plane of the drawing sheet. The magnetic field generated by a current in jaw 122 and its mating stab will have field lines that are approximately circular and that encircle jaw 122, and that lie in the plane of the drawing sheet. The orientation of sensor 210, as shown, makes its responsive axis approximately tangent to the circular field lines, thereby strengthening the sensor's response to the magnetic field radiated by the current in jaw 122.

In the schematic view of FIG. 2A, the dotted arrows indicate that power always flows from the top two jaws 120, 124 to the bottom two jaws 122, 126, respectively. Current carried by the neutral conductor does not enter the meter itself. This ultimately makes it easier to measure the two line currents separately, or to measure the sum of the two line currents, in the embodiments.

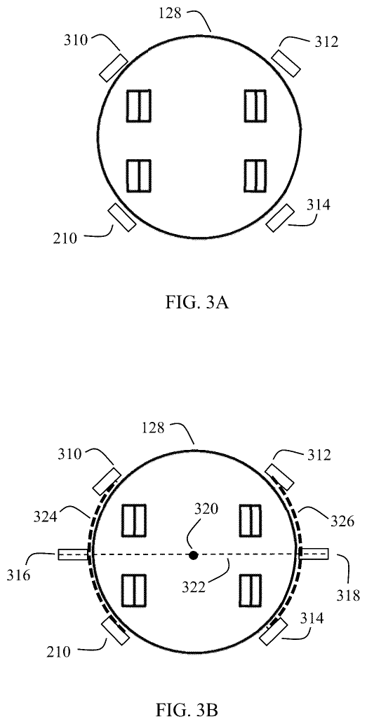

FIGS. 3A and 3B show examples of placement for embodiments comprising a plurality of magnetic field sensors. Referring to FIG. 3A, embodiments of the novel electricity sensor may comprise an array of magnetic sensors 210, 310, 312, 314, each being a magnetic field sensor, each mounted adjacent to perimeter 128, with each magnetic sensor targeting a different jaw 122, 120, 124, 126 and its mated stab, respectively. The magnetic sensor outputs may be processed separately, or, alternatively, the outputs may be combined in groups. Here, combining may mean combining in a linear fashion by adding or subtracting output signals from each other by using any of various devices or methods, including by using analog summation or difference amplifiers, or by digitizing output signals and adding or subtracting the resulting numbers digitally, for example. When combining outputs of the magnetic field sensors, a different predetermined gain constant may be used to multiply each output. When combining outputs of the magnetic field sensors, the phasing, or polarity of connection, of the outputs may be selected to be in phase (reinforcing), or out of phase (cancelling). For example, outputs from sensors such as coils that have electrically floating voltage outputs may be combined by simply connecting them together in in series, either in phase or out of phase.

If combined, the magnetic sensor outputs may be combined into a single group, or into two groups, for example. If combined into two groups, the groups may be used to make independent measurements of the first line current and of the second line current flowing through a respective first conductor and respective second conductor within the meter equipment, each magnetic sensor of a first group being disposed adjacent to a unique respective segment of the first conductor, each magnetic sensor of a second group being disposed adjacent to a unique respective segment of the second conductor. The output signals of the first group are combined to form a respective first combined output signal. The output signals of the second group are combined to form a respective second combined output signal. The sensitivities or gains of the sensors withing each group may be approximately matched. A central value of each combined output signal may be approximately proportional to a central value of its respective line current. These can be multiplied by an estimate of the line voltage, or by a measurement of the line voltage, typically 120 VAC in the U.S., to estimate the power attributable to each of the two lines.

If a combined sensitivity of the first group to the first line current is approximately matched to a combined sensitivity of the second group to the second line current, a central value of a sum of the first and second combined output signals may be approximately proportional to a sum of a central value of the first line current and a central value of the second line current. Then, the single central value may be used to represent the sum of the two line currents. This can be multiplied by an estimate or a measurement of the line voltage, typically approximately 120 VAC in the U.S., to estimate power, as before.

Referring to FIG. 3B, an embodiment of the novel electricity sensor may again comprise a plurality of magnetic sensors 210, 310, 312, 314, with each magnetic sensor targeting a different jaw-stab pair, as in FIG. 3A, but it may further include magnetic sensors 316, 318. Magnetic sensors 316, 318 are magnetic field sensors disposed adjacent to perimeter 128 at a predetermined distance and a predetermined orientation with respect to magnetic sensors 210, 310, 312, 314. The output signals of sensors 210, 310, 312, 314, 316, 318 are again combined to form a magnetic sensor signal. When combining the output signals, the phasing, or polarity of connection, of the magnetic sensor outputs may be selected so that sensors 316, 318 are out of phase (cancelling) with respect to those of sensors 210, 310, 312, 314. This may make the device more uniformly responsive to the current for a variety of different meters, meter sockets, and field wiring.

The responsive axis of magnetic sensors 316, 318 may be disposed so that an extension of a responsive axis of the each sensor approximately intersects a central axis of the meter. For example, in FIG. 3B, each of the sensors 316, 318 are assumed to have a responsive axis that is parallel to the long side of the rectangle shape that represents it in the figures. These axes are aligned with a straight dotted reference line 322 that passes through a center axis 320 of meter 112.

Magnetic sensors 316, 318 may have a selected tilt angle with respect to a plane of the cover of the meter socket. Again, before combining outputs of sensors 316, 318 with those of the other sensors 210, 310, 312, 314, a unique predetermined gain constant may be used to multiply each output.

The particular arrangements of the magnetic sensors discussed above and portrayed in the drawings should not be construed as limiting the scope of the embodiments but as merely providing illustrations of some of several embodiments.

In FIG. 3B, two electrodes 324, 326 are represented with curved dotted lines. Electrodes 324, 326 comprise conductors placed adjacent to meter 112 on its left and right sides, respectively. Electrode 324 is used to sense a phase of a voltage on conductors connected to jaws 120, 122 on the left side of meter socket 110, and electrode 326 is used to sense a phase of a voltage on conductors connected to jaws 124, 126 on the right side of meter socket 110. The operation of these electrodes will be discussed in more detail below.

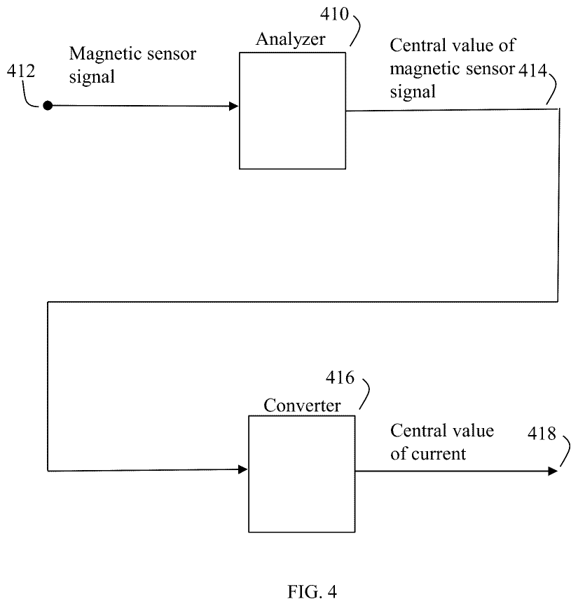

Referring to FIG. 4, embodiments of the electricity sensor may include an analyzer 410 for acquiring a magnetic sensor signal 412. Signal 412 may comprise an output or measurement from a single magnetic sensor or a combination of output signals or measurements from a plurality of magnetic sensors. Analyzer 410 processes magnetic sensor signal 412 to generate a central value of magnetic sensor signal 414. Embodiments may further include a converter 416 for converting central value of magnetic sensor signal 414 to a central value of current 418. Converter 416 may, in some embodiments, convert central value of magnetic sensor signal 414, or other measurements of the magnetic field, to central value of current 418 by either multiplying the central value of the magnetic sensor signal by a selected constant, or using the central value of the magnetic sensor signal to index values in a look up table, or using the central value of the magnetic sensor signal as an argument for a mathematical function. These methods should not be construed as limiting the scope of the embodiments but as merely providing examples of some of several embodiments.

A value or measurement of a magnetic field signal or of a current may be a central value such as a mean value, an average value, an expected value, a median value, a root mean square value, or a peak value, for example. Other kinds of central values may be calculated and used for display or analysis, in a conventional manner.

A direction of power flow may be determined by a sign of central value of current 418.

Alternatively, instantaneous values, or time sample series, of magnetic sensor signal 412 or its derivations may be used for display or analysis.

Analyzer 410 may determine central value of magnetic sensor signal 414 substantially at a fundamental frequency of, and at a predetermined phase shift relative to, the voltage on the conductor, whereby central value of magnetic sensor signal 414 may be used to estimate a central value of a component of the current having the fundamental frequency and phase of the voltage on the conductor, namely, central value of current 418. This may mitigate power factor error and susceptibility to noise and electromagnetic interference.

Analyzer 410 may comprise a phase sensitive detector, a synchronous detector, a single-phase synchronous detector, a dual-phase synchronous detector, a synchronous rectifier, a lock in amplifier, a single-phase lock-in amplifier, a dual-phase lock-in amplifier, a frequency analyzer, a spectrum analyzer, a cross correlator, a digital signal processor, or an analog signal processor, for example.

To determine central value of magnetic sensor signal 414 substantially at the fundamental frequency of, and at a predetermined phase shift relative to, the voltage on the conductor, some embodiments may include a reference signal generator that connects to analyzer 410 (this connection is not shown in FIG. 4). The reference signal generator provides a reference signal having approximately the fundamental frequency of a voltage on the conductor and having a predetermined phase with respect to a phase of the voltage on the conductor.

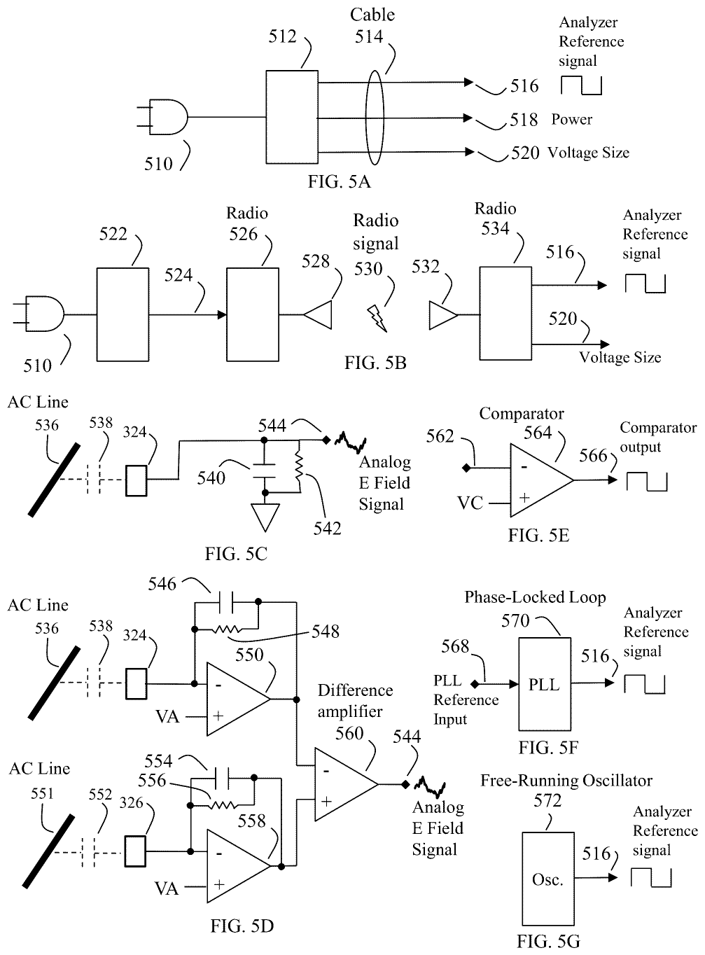

The reference signal generator may comprise a line voltage plug sensor with a wired output, a line voltage plug sensor with a wireless output, an electric field sensor, an electric field sensor connected to a comparator, an electric field sensor connected to a phase locked loop, or an electric field sensor connected to a phase locked loop having a digital oscillator with a plurality of selected operating frequencies, as discussed further below, and as shown in FIGS. 5A to 5G. The reference signal is designated as reference signal 516 in these figures.

FIG. 5A shows a reference signal generator that senses the voltage remotely with a galvanic connection. It connects to a dwelling's alternating current (AC) mains by using a line voltage plug 510 that is plugged into a standard residential receptacle by the user. Plug 510 connects to a line voltage plug sensor with wired output 512. Sensor 512 provides a reference signal 516 to analyzer 410 through a cable 514. Two other signals may optionally be generated and sent through cable 514: a power signal 518 and a voltage size signal 520. Power signal 518 can provide power to energize analyzer 410 or other electronics of the electricity sensor. Voltage size signal 520 can provide a measure of AC mains voltage to hardware or, if digitized, to software in a computing system, that estimates whole-house power. Voltage size signal 520 can be used to calculate power, thereby mitigating a +/−10.0% error in power estimations that might otherwise occur due to voltage variations if nominal voltage is assumed. Sensor 512 preserves the phase of the voltage on the AC mains in its reference signal 516, which ultimately allows phase-sensitive detection by the analyzer.

FIG. 5B shows a reference signal generator that again connects to the A.C. mains using line voltage plug 510. Plug 510 connects to a line voltage sensor 522, which connects to a radio 526, which connects to an antenna 528 that produces a radio signal 530. Radio signal 530 is received by an antenna 532. Antenna 532 connects to a radio 534, and radio 534 provides reference signal 516 to analyzer 410. Voltage size signal 520 may optionally be generated and used, as described above. Line voltage sensor 522 and radios 526, 534 preserve the phase of the voltage on the AC mains in reference signal 516, which ultimately allows phase-sensitive detection by the analyzer.

FIG. 5C shows a capacitively-coupled electric field sensor. This detects a phase of a voltage on a first AC line 536. First AC line 536 is a conductor that comprises, in part, left jaws 120,122 of meter socket 110 in this example. This is one of the two conductors whose current and voltage are effectively measured by meter 112. The phase of the voltage on first AC line 536 is sensed by electrode 324. Electrode 324 is disposed externally to and adjacent to the left side of meter 112 (as shown in FIG. 3B). A voltage of first AC line 536 is coupled through a parasitic coupling capacitor 538. First AC line 536 constitutes one plate of capacitor 538, and electrode 324 constitutes the other plate. Capacitor 538 and capacitor 540 together constitute a capacitive AC voltage divider whose output is analog electric (E) field signal 544. A resistor 542 establishes a direct current (DC) voltage bias of approximately 0.0 V. The capacitive voltage divider preserves the phase of the voltage on first AC line 536 in its output signal 544, which ultimately allows phase-sensitive detection by the analyzer. Signal 544 may be used directly as analyzer reference signal 516. Alternatively, signal 544 can be connected to a comparator input 562 of a comparator 564 of FIG. 5E, for example, and a comparator output 566 can be used directly as reference signal 516. In another alternative, referring to FIG. 5F, signal 544 can be connected to a phase locked loop (PLL) reference input 568 of a PLL 570, thereby producing reference signal 516. In yet another alternative, signal 544 can be connected to a comparator input 562 of a comparator 564, and comparator output 566 may be connected to PLL reference input 568, PLL 570 again thereby producing reference signal 516.

Use of a PLL may mitigate a susceptibility of reference signal 516 to noise and electromagnetic interference.

An alternative to the circuit of FIG. 5C is shown in FIG. 5D. This is a dual-electrode capacitively-coupled electric field sensor. In this example, the phase of the voltage on first AC line 536 is again sensed by electrode 324, on the left side of meter socket 110, as before. However, in this embodiment, a second electrode 326, located on the right side of meter socket 110, is added to additionally sense a phase of a voltage on a second AC line 551. AC line 551 may be a conductor that comprises, in part, jaws 124,126 on the right side of meter socket 110, for example. Electrode 326 may be disposed externally to and adjacent to the right side of meter 112 (as shown in FIG. 3B). The voltage on AC line 551 is coupled through a parasitic coupling capacitor 552 to electrode 326. In this example, opamps 550, 558 use feedback capacitors 546, 554 to again essentially form capacitive AC voltage dividers. However, the two opamp outputs are in opposite phase, owing to the opposite phases of the voltages on first and second AC lines 536, 551. The opamp outputs are combined by a difference amplifier 560 to produce analog E-field signal 544. Feedback resistors 548, 556 mitigate a DC output voltage that would otherwise be caused by bias and offset currents, and, again, establish a direct current (DC) voltage bias of approximately 0.0 V on analog E field signal 544. The capacitive voltage divider action preserves the phase of the voltage on first AC line 536 and second AC line 551 in signal 544, which ultimately allows phase-sensitive detection by the analyzer, so it can be used as was previously discussed for the circuit of FIG. 5C.

The placement of electrodes 324 and 326 on the left or right sides of meter 112 to sense voltage phase on either first AC line 536 or second AC line 551 may arbitrarily be reversed; changing the line conductor whose voltage is sensed will simply result in a change in polarity of the estimated line current, which must be accounted for.

Finally, referring to FIG. 5G, a free-running oscillator 572 with nominal frequency approximately equal to nominal line voltage frequency (typically 60.00 Hz in the United States) may be used to provide analyzer reference signal 516, if a dual-phase synchronous detector is employed, as will be discussed further below.

The waveform shape of analyzer reference signal 516 may be approximately that of a sinusoid, a complex sinusoid, a square wave, a triangle wave, or an arbitrary waveform. Although sinusoids and square waves will be intrinsically generated by certain of the embodiments shown in FIGS. 5A-5G, other waveshapes may be derived from these in a conventional manner and used.

The devices of FIGS. 5A-5G should not be construed as limiting the scope of the embodiments but as merely providing illustrations of some of several embodiments.

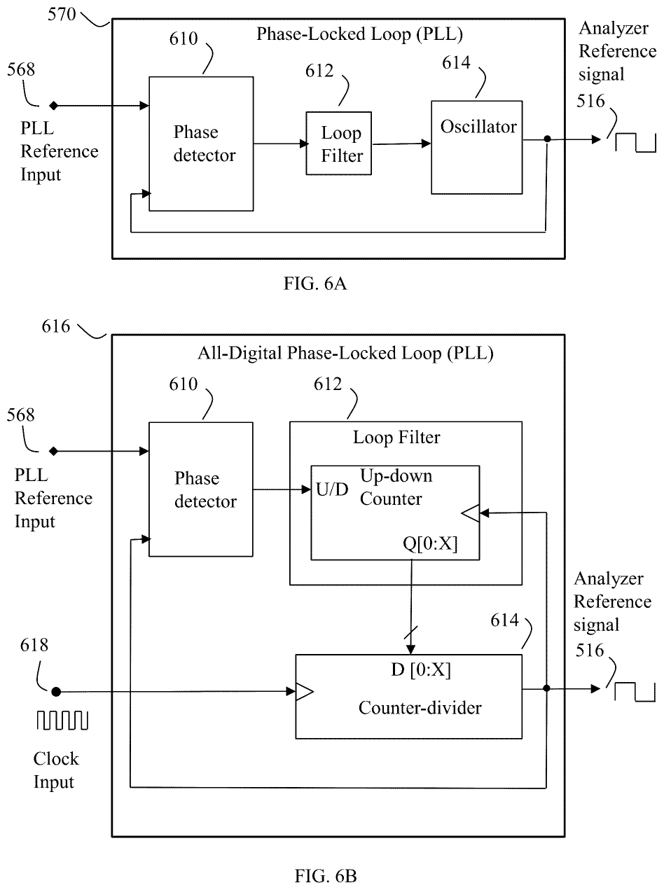

FIG. 6A shows an example of the internal structure of PLL 570, here depicting a generic PLL block diagram with a phase detector 610, a loop filter 612, and an oscillator 614. An embodiment of PLL 570 may be analog, hybrid analog and digital, or all-digital.

Characteristic aspects of the subject PLL application are, first, that a relatively narrow operating frequency range (for example, an operating frequency range of approximately 59.8 Hz to 60.2 Hz) may suffice for oscillator 614, and, second, that a relatively large pull-in time (for example, a pull-in time of approximately 10.0 seconds) may be allowable for the PLL. These aspects may be advantageously exploited by implementing oscillator 614 with an all-digital PLL design having appropriate attributes, which will now be discussed.

FIG. 6B shows a block diagram of an example of an all-digital PLL 616, which is an example of an implementation of PLL 570. In this embodiment, oscillator 614 comprises a programmable counter divider that generates a plurality of as few as two discrete frequencies that are approximately centered on the nominal AC line frequency of 60.00 Hz (for the United States). A clock input 618 of oscillator 614 connects to an accurate clock source. The clock source may be, for example, a low-cost, 32.768 KHz watch crystal oscillator. Phase detector 610 controls the U/D (UP/DOWN) input on the loop filter counter to select one of oscillator 614's operating frequencies, as appropriate, updating its frequency as often as once per each cycle of reference signal 516 in some embodiments. The number of frequencies generated by the all-digital minimal hardware PLL may be 2, 3, 4, or less than 16, for example. The all-digital PLL function can be implemented with logic that is small, simple, and low-cost.

The block diagram of FIG. 6B illustrates just one non-limiting example of an embodiment of an all-digital minimal hardware PLL, and skilled practitioners will recognize that many other implementations of substantially the same or similar function are possible. For example, the block diagram of FIG. 6B uses an up-down counter in loop filter 612 to provide different start counts to a programmable counter in oscillator 614, thereby generating different frequencies from oscillator 614. An alternative embodiment (not shown in FIG. 6B) would use pulse-stretching or period-stretching of the clock signal connected to clock input 618, with the extent of stretching commanded by phase detector 610, to generate two or more discrete oscillator frequencies from oscillator 614. Again, these are non-limiting examples, and one of ordinary skill in the art will recognize that many other implementations of substantially the same or similar function are possible.

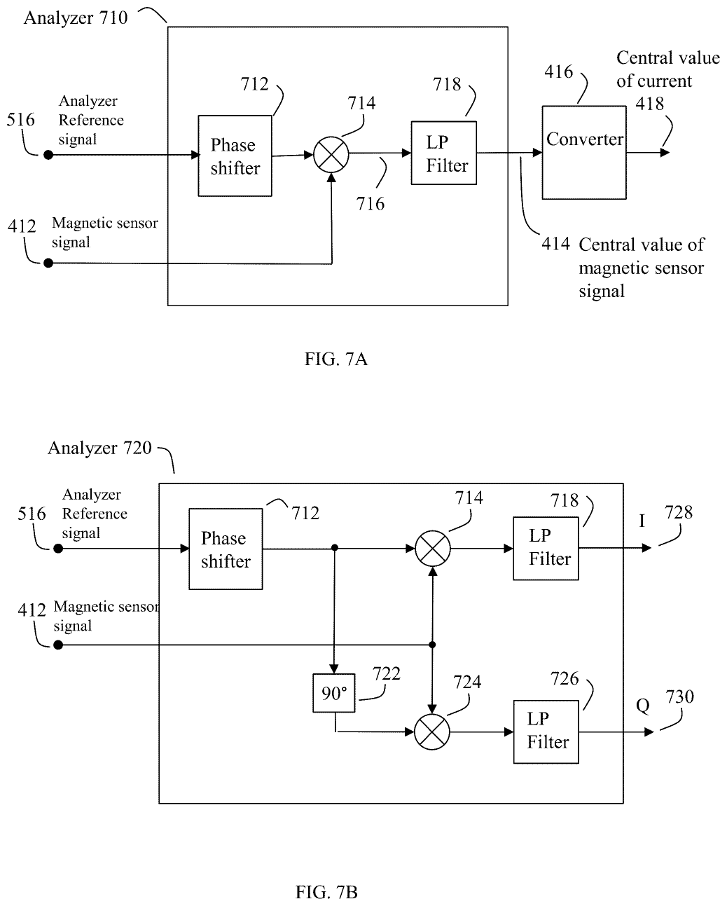

FIGS. 7A and 7B show block diagrams of synchronous detector embodiments of analyzer 410.

FIG. 7A shows a single-phase analyzer 710. Single-phase analyzer 710 is connected to analyzer reference signal 516 and to magnetic sensor signal 412. The analyzer determines central value of magnetic sensor signal 414 approximately at the fundamental frequency of, and at a predetermined phase shift relative to, the voltage on the conductor that is detected by a reference signal generator. Central value of magnetic sensor signal 414 may be approximately proportional to an amplitude of a component of the current in a target conductor having the phase of the voltage on the conductor. This may mitigate power factor error and susceptibility to noise and electromagnetic interference.

In FIG. 7A, single-phase analyzer 710 comprises a phase shifter 712 that phase shifts reference signal 516 to generate a phase shifted reference signal having a selected phase shift relative to the phase of the voltage, a multiplier 714 that multiplies magnetic sensor signal 412 by the phase shifted reference signal to create a product signal 716, and a lowpass filter 718 that filters product signal 716 to produce central value of magnetic sensor signal 414.

Lowpass filter 718 may comprise an integration, a summation, an average, a moving average, a digital filter, a digital infinite impulse response filter, a digital finite impulse response filter, or an analog filter.

To calculate real power (vs. reactive power), the component of current that is in phase with the conductor voltage is measured and used, and this current value is ultimately multiplied by a voltage value or a voltage signal. To measure this in-phase current component with an air-core coil type of magnetic sensor 210 such as conductor loop, a coil of conductive material, an inductor, or a Rogowski coil, for example, all of which produce a magnetic sensor signal 412 having a nominal 90° phase shift with respect to the conductor current in accordance with Lenz's Law, the predetermined phase shift of phase shifter 712 may be set to approximately 90° (or an odd integral multiple of) 90°, to account for the 90° phase shift between the conductor current and the resulting sensor output, magnetic sensor signal 412. Conversely, to accomplish this with a magnetic sensor that doesn't produce an intrinsic 90° phase shift, such as a Hall effect sensor, the predetermined phase shift of phase shifter 712 may be set to approximately 0° (or an integral multiple of 180° degrees); alternatively, phase shifter 712 may be entirely eliminated if no fine-tuning of phase is necessary. Sensors that employ an air-core conductor winding may be advantageous because when the predetermined phase shift is set to 90°, an undesired feedthrough of 120 VAC line voltage to the current sensor output, caused by parasitic capacitive coupling between the current sensors and the target conductors, is mitigated by analyzer 710.

Although phase shifter 712 is shown connected to reference signal 516 in FIG. 7A, the connections of reference signal 516 and magnetic sensor signal 412 may swapped; either reference signal 516 or magnetic sensor signal 412 may be phase-shifted with substantially the same result, although a change in sign may have to be accounted for.

When analyzer 710 is implemented using sampled data and digital signal processing, error may be mitigated if the multiplying and filtering is performed for an approximately integral number of cycles of the reference signal, i.e., processing is done over whole cycles versus including processing over just a portion of a cycle.

Now referring to FIG. 7B, a dual-phase embodiment of analyzer 410 is shown as dual-phase analyzer 720. Dual-phase analyzer 720, in part, comprises the same elements as single-phase analyzer 710, and these are used to generate an in-phase output (I) 728. However, dual-phase analyzer 720 further includes a second channel comprising a 90° phase shifter 722, a second multiplier 724, and a second lowpass filter 726 that are used to generate a quadrature output (Q) 730. For this dual-phase analyzer 720, central value of magnetic signal 414 may be calculated as central value of magnetic signal=\sqrt{I²+Q²}.

A dual-phase synchronous detector may be advantageous in at least two situations.

First, in some situations the detection of voltage phase may be compromised, thereby corrupting reference signal 516. For example, a particular model utility meter may be electrostatically shielded. Then, if the reference signal generator uses a capacitively-coupled electric field sensor but doesn't use a PLL, reference signal 516 may be entirely interrupted. However, if a PLL such as PLL 616 with a sufficiently narrow oscillator frequency range, such as 59.8 Hz to 60.2 Hz, is used in the reference signal generator, then, even in the absence of PLL phase lock, dual-phase analyzer 720 may still estimate central value of magnetic sensor signal 414.

Secondly, if non-unity power factor and reactive power aren't a concern (if, for example, it is anticipated that most loads will produce a power factor of approximately 1.0), it may be deemed that no detection of voltage phase is required for the reference signal generator. In this case, the system may be simplified by omitting voltage phase detection, and free-running oscillator 572 having a fundamental frequency (for example, 60.0 Hz) that is approximately equal to a fundamental frequency of the voltage on the conductor may be employed to generate reference signal 516 for analyzer 720. In both cases, the mode of operation still allows narrow-band detection; however, the lack of voltage phase information will compromise mitigation of capacitively-coupled line voltage crosstalk, and the electricity sensor won't be able to distinguish between real and reactive power.

For a dual-phase synchronous detector embodiment such as that shown in FIG. 7B, if no fine-tuning of phase shift is deemed necessary, and only 0° phase shift and 90° phase shift are required, one of the two phase shifters 712, 722 may be eliminated and just a single 90° phase shifter can be used. Multiplier 714 may be connected directly to magnetic sensor signal 412, and multiplier 724 can be connected to a 90° phase shifted version of magnetic sensor signal 412, for example. The resulting I, Q signals 728, 730 can then be used as described above.

When a synchronous detector like those of FIG. 7A or 7B is used with a reference signal generator having an electric field sensor like those of FIG. 5C or 5D that detects voltage phase through the dome of meter 112, the direction of power flow through meter 112 (top to bottom for net consumption, bottom-to-top for net generation) may be determined by a sign of the central value of the current. This is because the sensors of FIGS. 5C and 5D can definitively determine the relative phase of the current and the voltage in the targeted conductor (first AC line 536 or second AC line 551). Conversely, when a synchronous detector is used with a remote reference signal generator such as those depicted in FIGS. 5A and 5B that employs plug 510, unless the mating receptacle can be identified as being connected to first AC line 536 or second AC line 551, the phase information provided may have a +/−180° ambiguity, so the direction of power flow may be ambiguous.

FIGS. 8A-8F illustrate examples of physical layouts of sensors, electrodes, mounting bases, and alignment elements, for embodiments. For clarity, sensors 316, 318, interconnecting wires and cables, and supporting electronics such as would be needed to implement analyzers, converters, radios, antennas, and batteries, are not shown in these figures. Although these figures contain many specificities, these should not be construed as limiting the scope of the embodiments but as merely providing illustrations of some of several embodiments.

FIGS. 8A, 8B show a top view and side view, respectively, of a single sensor embodiment comprising a base 810, a single magnetic sensor 210, and a single electrode 324. In this example, base 810 comprises a rigid rectangular sheet. Base 810 may be a PCB or other electrically insulating substrate or housing part. Base 810 may even comprise a conductive metal rectangular sheet, for example, if care is taken to insulate any sensor electrical connections from the base. Base 810 may be mounted on or adjacent to cover 114, adjacent to perimeter 128, and adjacent to one of the jaws 120, 122, 124, 126. An example of this placement is shown in FIGS. 2A and 2B, wherein magnetic sensor 210 is placed adjacent to jaw 122. This placement nominally allows monitoring of only one of two line currents I_{L1} and I_{L2}, and represents a substantially minimal realization of sensor layout for an embodiment, although electrode 324 might be omitted in certain embodiments.

Alternatively, to sense both line currents I_{L1} and I_{L2} with one magnetic sensor, a single sensor assembly, like the one shown in FIG. 8A, with base 810 may mount adjacent to perimeter 128 and adjacent to two jaws 120, 124, on the top of meter socket 110 or adjacent to two jaws 122, 126 on the bottom of meter socket 110. These latter two placements allow monitoring both line currents I_{L1} and I_{L2} with only one sensor, and again represent a substantially minimal realization of sensor layout for an embodiment. In another alternative for sensing both line currents I_{L1} and I_{L2}, two single sensor assemblies, like the one shown in FIG. 8A, can be deployed adjacent to perimeter 128, one adjacent to two jaws on top 120, 124, and another adjacent to perimeter 128, and adjacent to two jaws on bottom 122, 126. In yet another alternative for sensing both line currents I_{L1} and I_{L2}, a pair of single sensor assemblies (like the one shown in FIG. 8A) can again be deployed adjacent to perimeter 128—one on the left side, and another on the right side of cover 114. Each of these alternative embodiments (not shown in figures) may use a different selected orientation of the responsive axis of sensor 210 to align the responsive axis 210 with a magnetic field line radiated by the conductor.

Alternately, the novel sensor may comprise an annular ring assembly comprising a plurality of magnetic sensors arranged in an array, such as were illustrated schematically in FIGS. 3A, 3B. Such an assembly may be installed by sliding it over the dome of the utility meter and seating it.

FIGS. 80, 8D show a top view and side view, respectively, of such an annular ring sensor assembly comprising base 812, four magnetic sensors 210, 310, 312, 314, and two electrodes 324 and 326. Using magnetic field sensors that target all four jaws 120, 122, 124, 126 of socket 110 may engender a more uniform sensor gain across different models and makes of sockets 110, different models and makes of meters 112, and different routings of field wiring within sockets 110.

FIGS. 8E, 8F show a top view and side view, respectively, of a partial annular ring sensor assembly. In these figures, base 814 has a cutout on the bottom (shown) or on the top (not shown). The partial annular ring sensor assembly is otherwise similar to the annular ring sensor assembly of FIGS. 8C and 8D. The cutout may be desirable to reduce materials, and to make the orientation of the assembly easily discernable.

FIGS. 8D, 8F illustrate details of ring style and ringless mounting, respectively. FIG. 8D shows an example of mounting with a ring style socket (meter ring 130 is shown here in sectional view). Base 812 substantially seats on or adjacent to meter ring 130. In contrast, for a ringless style socket, the base substantially seats on perimeter 128. FIG. 8F shows base 814 mounted on a ringless style meter socket, adjacent to perimeter 128 of meter socket cover 114 (perimeter 128 is shown here in sectional view). Because the two mounting styles are designed to accommodate the same meters, the inside diameter of ring 130 and the diameter of the opening defined by perimeter 128 are substantially the same, and so a mounting base of an embodiment that fits ring 130 will approximately fit perimeter 128 also.

Embodiments may include one or more mounting alignment elements. For example, the alignment elements may be bosses that are attached to, or molded into, or protrude from, a base or protective enclosure of a sensor assembly. An alignment element helps to fix the disposition of a base 810, 812, 814, so that registration of a sensor or sensor array with respect to socket 110 or meter 112 (and their jaws and stabs) is made more constant. This mitigates a variation in sensor gain that may occur due to variations in sensor placement.

FIGS. 8D, 8F show examples of alignment elements. Mounting alignment elements 816, 818, 820, 822 are attached to and protrude from bases 812, 814.

The disposition of a mounting alignment element may be constrained by contact with meter ring 130 (as shown in FIG. 8D), perimeter 128 (as shown in FIG. 8F), the circular opening of cover 114, cover 114 itself, socket 110, a rim of meter 112, or a dome of meter 112, for example.

Labels or markings on the base, or a housing or enclosure of the base, or the sensor may be included to aid the user in orienting an embodiment. Label 824 is an example of this. After sliding the sensor assembly over the meter dome, a user rotates the assembly so that label 824 is on top. The resulting more uniform orientation helps to mitigate variation in sensor gain.

Although FIGS. 8A-8F and their descriptions, above, contain many specificities, these should not be construed as limiting the scope of the embodiments but as merely providing illustrations of some of several embodiments. For just one example, a circular band (not shown) substrate or housing part may be used as a base instead of the annular ring of base 812 to mount the sensors on the meter equipment. One of ordinary skill in the art will recognize various alternatives to the specific embodiments described herein, and will recognize that many other structures with various cross-sections, shapes, and materials may be used for bases 810, 812, 814.

As disclosed above, the electricity sensor's magnetic sensors and electrodes are located adjacent to perimeter 128 of cover 114. However, other elements used to implement an embodiment of the of the electricity sensor—for example, any electronics used to implement analyzers 410, 710, 720, converter 416, the reference signal generators shown in FIGS. 5A-5G, the PLLs of FIGS. 6A and 6B, and any batteries—may either be located on base 810, 812, 814, or, alternatively, be housed in a separate enclosure at another location and connected by a cable (separate enclosure and cable not shown in figures).

The base of a sensor assembly, such as base 810, 812, 814, may be fastened to cover 114 or 136, or to meter ring 130, or to any other part of the meter equipment by using small permanent magnets, or permanent magnet strip, or with adhesives or adhesive strips, or with reusable fasteners such as hook-and-loop or similar fasteners, or with clips, or with wires, or with cable ties, or by using any other conventional mechanical fasteners or conventional fastening method. The base may even be oriented or fastened by the use of clips in contact with the dome of meter 112 itself, or by using any other conventional mechanical fastener.

If AC mains voltage size is measured with either an integrated monitor (as in FIGS. 5A, 5B), or with another (perhaps third-party) remote voltage monitor, and measurements from that voltage monitor are conveyed to the electricity sensor or the user's smartphone by, for example, a wired link or radio link, maximum worst-case error in power estimations may be reduced by approximately 10%.

Various other configurations of analyzers 410, 710, 720, converter 416, the reference signal generators shown in FIGS. 5A-5G, the PLLs of FIGS. 6A and 6B, may also be used, with particular elements being implemented in software, firmware, or a combination thereof. One of ordinary skill in the art will recognize various alternatives to the specific embodiments described herein.

Analyzer 410 and converter 416 may comprise any machine comprising any conventional combination of hardware and software able to perform the signal processing, examples of which are shown in FIGS. 5A-5G, 6A, 6B, 7A, and 7B for analyzer 410. Hardware such as combinational logic and memory, a Field Programmable Logic Array (FPGA), a Digital Signal Processor (DSP), or an Application Specific Integrated Circuit (ASIC), may be used to implement these, for example. Alternatively, a software program that implements signal processing, running on a computing device such as a DSP, an embedded microprocessor, a general-purpose computer, or a Personal Computer (PC), may be used, for example. All of this is also true for converter 416.

The various signal processing embodiments of analyzer 410 and converter 416 and the associated wired or wireless links and display can be implemented in a wide variety of operating environments, which in some cases can include one or more user computers or computing devices which can be used to operate any of a number of applications. User or client devices can include any of a number of general-purpose personal computers, such as desktop or laptop computers running a standard operating system, as well as cellular, wireless and handheld devices running mobile software and capable of supporting a number of networking and messaging protocols. Such a system can also include a number of workstations running any of a variety of commercially available operating systems and other known applications for purposes such as development and database management. These devices can also include other electronic devices, such as dummy terminals, thin-clients, gaming systems and other devices capable of communicating via a network.

The novel sensor may be integrated with a conventional data acquisition subsystem, communication subsystem, and computing system. It may calculate electricity consumption using the value of the current and an estimate of a voltage on the conductor, and provide the calculated electricity consumption to a user by any conventional means. It may transmit information in a conventional manner, using a wired connection, using a Bluetooth, WIFI, or any other conventional wireless link, to any conventional display, or to be stored on any conventional storage system. For example, information may be displayed on a dedicated local or remote display unit, or be sent to a desktop or laptop or tablet computer, or to a user's smartphone for display or storage.

Some descriptions provided herein of example embodiments reference sampled-data aspects, such as discrete-time and discrete-amplitude sampling, and digital signal processing. These were provided as examples, but do not preclude the implementation of the embodiments in analog or continuous-time or continuous-amplitude methods or devices. Some descriptions provided herein of example embodiments reference analog aspects. Again, these were provided as examples, but do not preclude the implementation of the embodiments by using sampled-data methods, such as discrete-time and discrete-amplitude sampling, and digital signal processing.

Although the description above contains many specificities, these should not be construed as limiting the scope of the embodiments but as merely providing illustrations of some of several embodiments.

Based on the disclosure and teachings provided herein, a person of ordinary skill in the art will appreciate other ways and/or methods to implement the various embodiments.

Thus, the scope of the embodiments should be determined by the appended claims and their legal equivalents, rather than by the examples given.

I claim:

1. A device for measuring a current in a conductor within a meter equipment being used for residential fiscal metering of electricity, comprising
a. a magnetic field sensor for producing a magnetic sensor signal, the magnetic field sensor being disposed externally to the meter equipment and substantially adjacent to a perimeter of a circular opening in a cover of the meter equipment, the magnetic field sensor being substantially coupled to a magnetic field radiated from within the meter equipment by the current in the conductor, and
b. a base for mounting the magnetic field sensor on the meter equipment at a predetermined location and orientation, the base being disposed externally to and adjacent to the meter equipment, the base being interposed between the magnetic field sensor and an external surface of the meter equipment,
whereby the magnetic sensor signal may be used to estimate a value of the current.

2. The device of claim 1, wherein the magnetic field sensor is further disposed substantially adjacent to the conductor.

3. The device of claim 2, wherein the conductor comprises a jaw and a mated stab of the meter equipment.

4. The device of claim 1, wherein a responsive axis of the magnetic field sensor is disposed so that the responsive axis is approximately aligned with a magnetic field line radiated by the current in the conductor.

5. The device of claim 1, wherein the base has at least one mounting alignment element whose disposition with respect to that of the magnetic field sensor is fixed, and whose disposition when the device is mounted to the meter equipment is constrained by contact with the meter equipment, the mounting alignment element thereby constraining a disposition of the magnetic field sensor,
whereby a tolerance of a gain of the device may be reduced.

6. The device of claim 1, further comprising an analyzer for acquiring the magnetic sensor signal and for determining a value of the magnetic sensor signal.

7. The device of claim 6, wherein the analyzer comprises an element selected from the group consisting of a single phase synchronous detector and a dual phase synchronous detector.

8. The device of claim 1, further comprising a converter for converting a value of the magnetic sensor signal to the value of the current.

9. The device of claim 1, further comprising a reference signal generator for generating a reference signal, the reference signal having a predetermined phase with respect to a phase of a voltage on the conductor and a fundamental frequency that is approximately equal to a fundamental frequency of the voltage, and an analyzer for determining a central value of the magnetic field substantially at the fundamental frequency of, and at approximately the phase of, the voltage, the analyzer being connected to the reference signal and to the magnetic sensor signal,
whereby the central value of the magnetic field may be used to estimate a central value of a component of the current having approximately the fundamental frequency of the voltage and approximately the phase of the voltage, and power factor error and susceptibility to noise and electromagnetic interference may be mitigated.

10. The device of claim 9, wherein the reference signal generator comprises an element selected from the group consisting of a line voltage plug sensor with a wired output, a line voltage plug sensor with a wireless output, an electric field sensor, an electric field sensor connected to a comparator, an electric field sensor connected to a phase locked loop, and an electric field sensor connected to a phase locked loop having a digital oscillator with a plurality of selected operating frequencies.

11. The device of claim 1, further comprising a reference signal generator for generating a reference signal, the reference signal generator comprising a free running oscillator having a fundamental frequency that is approximately equal to a fundamental frequency of a voltage on the conductor, and an analyzer, the analyzer being connected to the reference signal and to the magnetic sensor signal, the analyzer comprising a dual phase synchronous detector for determining a central value of the magnetic sensor signal substantially at the fundamental frequency of the voltage,
whereby the central value of the magnetic field may be used to estimate a central value of a component of the current having approximately the fundamental frequency of the voltage, and a susceptibility to noise and electromagnetic interference may be mitigated without sensing a phase of the voltage.

12. A device for measuring a current in a conductor within a meter equipment being used for residential fiscal metering of electricity, comprising
a. a plurality of magnetic field sensors disposed in an array externally to the meter equipment and substantially adjacent to a perimeter of a circular opening in a cover of the meter equipment, the magnetic field sensors being substantially coupled to magnetic fields radiated from within the meter equipment by the current in the conductor, each magnetic field sensor having a respective output signal, the output signals being combined to form a magnetic sensor signal, and
b. a base for mounting the magnetic field sensors on the meter equipment in an array at respective predetermined locations and orientations, the base being disposed externally to and adjacent to the meter equipment, the base being interposed between the magnetic field sensors and an external surface of the meter equipment,
whereby the magnetic sensor signal may be used to estimate a value of the current.

13. The device of claim 12, wherein the output signals are combined in phase.

14. The device of claim 12, wherein at least one output signal is combined out of phase,
whereby the device may be more uniformly responsive to the current for a variety of different meters, meter sockets, and field wiring.

15. The device of claim 12, wherein a responsive axis of at least one magnetic field sensor is disposed so that an extension of the responsive axis approximately intersects a central axis of the meter,
whereby the device may be more uniformly responsive to the current for a variety of different meters, meter sockets, and field wiring.

16. A method for estimating a value of a current in a conductor within a meter equipment being used for residential fiscal metering of electricity, the method comprising
a. mounting on the meter equipment a magnetic field sensor for measuring magnetic fields, the magnetic field sensor being placed externally to the meter equipment and substantially adjacent to a perimeter of a circular opening in a cover of the meter equipment,
b. measuring, with the magnetic field sensor, magnetic fields that are substantially radiated from within the meter equipment by the current in the conductor, thereby producing measurements of the magnetic fields,
c. determining the value of the current from the measurements of the magnetic fields.

17. The method of claim 16, wherein the measuring further comprises measuring components of the magnetic fields that are approximately aligned with magnetic field lines substantially radiated by the current in the conductor.

18. The method of claim 16, wherein the determining comprises a step selected from the group consisting of multiplying the measurements by a selected constant, using the measurements to index values in a look up table, and using the measurements as arguments for a mathematical function.

19. The method of claim 16, wherein the determining comprises generating a reference signal having a predetermined phase with respect to a phase of a voltage on the conductor and a fundamental frequency that is approximately equal to a fundamental frequency of the voltage, and using the reference signal to determine a central value of the measurements of the magnetic fields substantially at the fundamental frequency of, and at approximately the phase of, the voltage,
whereby the central value of the measurements of the magnetic fields may be used to estimate a central value of a component of the current having approximately the fundamental frequency of the voltage and approximately the phase of the voltage, and power factor error and susceptibility to noise and electromagnetic interference may be mitigated.

20. The method of claim 19, wherein the generating comprises a step selected from the group consisting of sensing an electric field externally to and adjacent to the meter equipment to generate the reference signal, and sensing the voltage remotely with a galvanic connection to generate the reference signal.
